(19) United States
(12) Patent Application Publication
(10) Pub. No.: US 2013/0294141 A1
(43) Pub. Date: Nov. 7, 2013

(54) MEMORY DEVICE INCLUDING ANTIFUSE MEMORY CELL ARRAY AND MEMORY SYSTEM INCLUDING THE MEMORY DEVICE

(71) Applicant: SAMSUNG ELECTRONICS CO., LTD., Suwon-si (KR)

(72) Inventors: Se-Il Oh, Incheon (KR); Sung-Hoon Kim, Seongnam-si (KR); Soo-Young Kim, Seoul (KR); Joung-Yeal Kim, Yongin-si (KR); Ho-Cheol Lee, Yongin-si (KR)

(73) Assignee: SAMSUNG ELECTRONICS CO., LTD., Suwon-si (KR)

(21) Appl. No.: 13/803,612

(22) Filed: Mar. 14, 2013

(30) Foreign Application Priority Data
May 4, 2012 (KR) 10-2012-0047529

(51) Int. Cl. G11C 17/18; G11C 17/16

(52) U.S. Cl. CPC G11C 17/18; G11C 17/16
USPC 365/96

(57) ABSTRACT

A memory device includes a memory cell array, a column decoder, and a row decoder. The row decoder includes a first word line driver and a second word line driver. The first word line driver is configured to electrically coupled to a first set of antifuse memory cells coupled to a first word line. The second word line driver is configured to electrically coupled to a second set of antifuse memory cells coupled to a second word line. The first set of antifuse memory cells are arranged in first and third rows of the memory cell array, and the second set of antifuse memory cells are arranged in second and fourth rows of the memory cell array. The second row is arranged between the first and third rows.

### CROSS-REFERENCE TO RELATED APPLICATIONS

This application claims priority under 35 U.S.C. §119(a) to Korean Patent Application No. 10-2012-0047529 filed on May 4, 2012, the disclosure of which is hereby incorporated by reference in its entirety.

### BACKGROUND

The embodiments disclosed herein relate to a memory device, and more particularly, to a memory device having a layout for efficiently using a chip area.

In general, programmable memory is used in devices, such as micro controller units (MCUs), power integrated circuits (ICs), display driver ICs, and complementary metal oxide semiconductor (CMOS) image sensors, used as mobile parts or automobile parts. For such programmable memory, one-time programmable (OTP) memory, which occupies a small area, does not require an additional process, and is programmed by electrically shorting with a breakdown mechanism when a high voltage is applied to a thin gate oxide layer, is usually used. Programmable memory devices such as OTP memory devices are usually programmed by breaking connections (using fuses) or creating connections (using antifuses) in a memory circuit. For instance, phase-change read-only memory (PROM) includes a fuse and/or an antifuse at a memory position or a bit and is programmed by triggering the fuse or the antifuse. Once programming is done, it is usually irreversible. Usually, programming is carried out for a particular end use or carried out in the light of applications after memory products are manufactured.

Fuse connection is implemented by resistive fuse elements that open or break at a certain amount of high current. Antifuse connection is implemented by a thin barrier formed of a non-conductive material (like silicon dioxide) between two conductive layers or terminals. When a certain high voltage is applied to the terminals, silicon dioxide or such non-conductive material becomes a short-circuit or a low-resistance conductive passage between the two terminals.

Since design of peripheral circuits of programmable antifuse cell arrays is not simple, a large area is typically used in the layout when row decoders and sense amplifiers are constructed in the ratio of one to one.

### SUMMARY

According to some embodiments, there is provided a memory device including a memory cell array, a row decoder, and a column decoder. The memory cell array includes a plurality of antifuse memory cells electrically coupled to a plurality of bit lines and a plurality of word lines. The column decoder is configured to select one bit line among the plurality of bit lines. The row decoder is configured to select one word line among the plurality of word lines. The row decoder includes a first word line driver and a second word line driver. The first word line driver is configured to output a first word line selection signal to a first word line, and is electrically coupled to a first set of antifuse memory cells coupled to the first word line. The second word line driver is configured to output a second word line selection signal to a second word line, and is electrically coupled to a second set of antifuse memory cells coupled to the second word line. The first set of antifuse memory cells are arranged in first and third rows of the memory cell array, and the second set of antifuse memory cells are arranged in second and fourth rows of the memory cell array. The second row is arranged between the first and third rows.

According to other embodiments, there is provided a memory device including a memory cell array, a column decoder, a first row decoder, a second row decoder, and a sense amplifier. The memory cell array includes a plurality of sub arrays each including a plurality of antifuse memory cells arranged in rows and columns and electrically coupled to a plurality of bit lines and a plurality of word lines. The column decoder is configured to output a plurality of bit line selection signals and to select one bit line among the bit lines in response to one of the bit line selection signals. The first row decoder is configured to output a first word line selection signal and to select a first word line in response to the first word line selection signal, the first row decoder electrically coupled to a first set of antifuse memory cells arranged in a first row and a third row. The second row decoder is configured to output a second word line selection signal and to select a second word line in response to the second word line selection signal, the second row decoder electrically coupled to a second set of antifuse memory cells arranged in a second row and a fourth row. The sense amplifier is configured to sense and amplify data of a selected antifuse memory cell. The second row is arranged between the first and third rows.

According to other embodiments, there is provided an antifuse device including an antifuse memory cell array, a column decoder, and a row decoder. The antifuse memory cell array includes a plurality of antifuse memory cells arranged in rows and columns and electrically coupled to a plurality of bit lines and a plurality of word lines. The column decoder is configured to be electrically coupled to the bit lines, to output a plurality of bit line selection signals, and to select one bit line among the bit lines in response to one of the bit line selection signals.

The row decoder includes a first word line driver and a second word line driver. The first word line driver is configured to output a first word line selection signal, and is electrically coupled to a first set of antifuse memory cells arranged in a first and a third row. The second word line driver is configured to output a second word line selection signal, and is electrically coupled to a second set of antifuse memory cells arranged in a second and a fourth row. The third row is arranged between the second row and the fourth row. A first bit line electrically coupled to the antifuse memory cell array is connected to a third set of antifuse memory cells arranged in a first column. The third set of antifuse memory cells includes at least one antifuse memory cell of each of the first and second set of antifuse memory cells.

### BRIEF DESCRIPTION OF THE DRAWINGS

The present disclosure will become more apparent by describing in detail exemplary embodiments thereof with reference to the attached drawings in which:

FIG. 1 is an exemplary conceptual diagram of a memory device including an antifuse memory cell array according to some embodiments;

FIG. 2 is a circuit diagram of an antifuse memory cell;

FIG. 3 is an exemplary block diagram of an antifuse device according to one embodiment;

FIG. 4 is an exemplary block diagram of an antifuse device according to one embodiment;

FIG. 5 is an exemplary block diagram of an antifuse device according to one embodiment;

FIG. 6 is an exemplary block diagram of an antifuse device according to one embodiment;

FIG. 7 is an exemplary block diagram of an antifuse device according to one embodiment;

FIG. 8 is an exemplary block diagram of an antifuse device according to one embodiment;

FIG. 9 is an exemplary block diagram of an antifuse device according to one embodiment;

FIG. 10 is an exemplary block diagram of an antifuse device according to one embodiment;

FIG. 11 is an exemplary block diagram of an antifuse device according to one embodiment;

FIG. 12 is an exemplary block diagram of an antifuse device according to one embodiment;

FIG. 13 is an exemplary block diagram of an antifuse device according to one embodiment;

FIG. 14 is an exemplary block diagram of an antifuse device according to one embodiment;

FIG. 15 is an exemplary block diagram of an antifuse device according to one embodiment;

FIG. 16 is an exemplary block diagram of a memory device according to some embodiments.

FIG. 17 is an exemplary block diagram of a data processing system including a memory system according to some embodiments;

FIG. 18 is an exemplary block diagram of a data processing system including the memory system according to some embodiments;

FIG. 19 is an exemplary block diagram of a data processing system including a plurality of memory devices according to some embodiments;

FIG. 20 is an exemplary block diagram of a data storage system including a plurality of memory modules according to some embodiments;

FIG. 21 is an exemplary block diagram of a memory module including a plurality of memory devices according to some embodiments; and

FIG. 22 is an exemplary schematic conceptual diagram of a multi-chip package 1000 including a plurality of semiconductor devices according to some embodiments.

### DETAILED DESCRIPTION OF THE EMBODIMENTS

Various example embodiments now will be described more fully hereinafter with reference to the accompanying drawings, in which embodiments of the disclosure are shown.

The present disclosure may, however, be embodied in many alternate forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.). As used herein, the term “and/or” includes any and all combinations of one or more of the associated listed items and may be abbreviated as “/”.

It will be understood that, although the terms first, second, etc. may be used herein to describe various elements, these elements should not be limited by these terms. Unless the context indicates otherwise, these terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms, such as “comprises,” “comprising,” “includes,” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein are to be interpreted as is customary in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

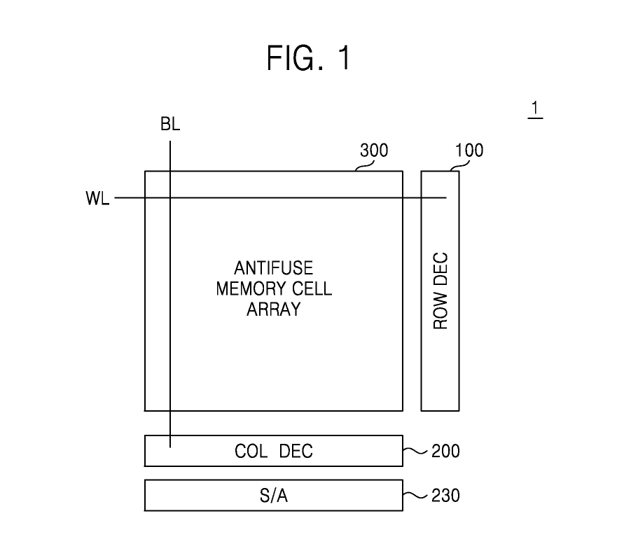

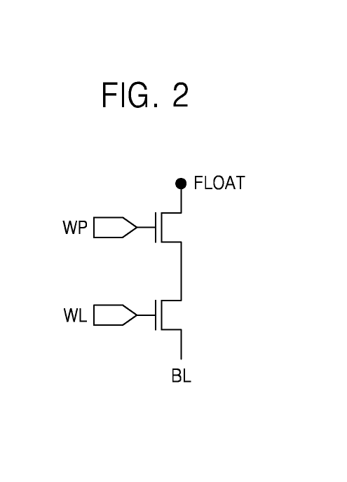

FIG. 1 is an exemplary conceptual diagram of a memory device 1 (hereinafter, referred to an antifuse device) including an antifuse memory cell array 300 according to some embodiments. FIG. 2 is a circuit diagram of an antifuse memory cell. Referring to FIG. 1, the antifuse device 1 may be included in a memory device (not shown). The antifuse device 1 includes a row decoder 100, a column decoder 200, the antifuse memory cell array 300, and a sense amplifier 230.

The antifuse memory cell array 300 includes a plurality of antifuse memory cells. Each of the antifuse memory cells is connected between a bit line BL and a word line WL as illustrated in FIG. 2. Each antifuse memory cell may include two transistors. A first transistor is a rupture transistor having a gate connected to a high-voltage line WP, a source connected to a floating terminal FLOAT, and a drain connected to a source of a second transistor. The second transistor is an access transistor having a gate connected to the word line WL, the source connected to the drain of the first transistor, and a drain connected to the bit line BL.

The antifuse memory cell array 300 may include a plurality of sub arrays. Each of the sub arrays includes a plurality of antifuse memory cells, a plurality of bit lines, and a plurality of word lines. The antifuse memory cells are connected between the bit lines and the word lines.

For instance, when the antifuse memory cell array 300 includes 10,000 (e.g., 100×100) cells, it may include two 100×50 sub arrays. The sub arrays may be arranged in line longitudinally, so that an entire array is 100 bit lines×100 word lines. Alternatively, the antifuse memory cell array 300 may include two 100×50 sub arrays. The sub arrays may be arranged in line laterally, so that an entire array is 200 bit lines×50 word lines.

The column decoder 200 is connected to the bit lines BL connected to the antifuse memory cells in the antifuse memory cell array 300. The column decoder 200 may decode bit line addresses of target memory cells received from a control logic (not shown) and output a plurality of bit line selection signals. The column decoder may include a plurality of column select transistors (not shown). Each of the column select transistors may be connected to a bit line and the bit line may be selected in response to one of the bit line selection signals. The column decoder 200 may be located in a side of the antifuse memory cell array 300.

The sense amplifier 230 is connected to the column select transistor of the column decoder 200 and senses and amplifies selected bit line signal.

When the antifuse memory cell array 300 includes a plurality of sub arrays, the position of the column decoder 200 varies with the arrangement of the sub arrays. For instance, it is assumed that the antifuse memory cell array 300 is an array having a first side and a second side perpendicular to the first side.

The column decoder 200 may be positioned at the first side of the memory cell array to access the bit lines depending on the arrangement of the sub arrays. Alternatively, the column decoder 200 may include a first column decoder positioned at the first side of the memory cell array and a second column decoder positioned at a third side of the memory cell array opposite to the first side. The first column decoder may access some of the bit lines through the first side and the second column decoder may access the remaining bit lines through the third side. This will be described in detail later.

The row decoder 100 is connected to the word lines WL connected to the antifuse memory cells in the antifuse memory cell array 300. The row decoder 100 may decode word line addresses of target memory cells received from the control logic and output a plurality of word line selection signals. The row decoder 100 may be arranged at a side of the memory cell array 300.

The row decoder 100 may be positioned at the second side of the memory cell array 300 to access the word lines depending on the arrangement of the sub arrays. Alternatively, the row decoder 100 may include a first row decoder positioned at the second side of the memory cell array 300 and a second row decoder positioned at a fourth side of the memory cell array 300 opposite to the second side. The first row decoder may access some of the word lines through the second side and the second row decoder may access the remaining word lines through the fourth side. This will be described in detail later.

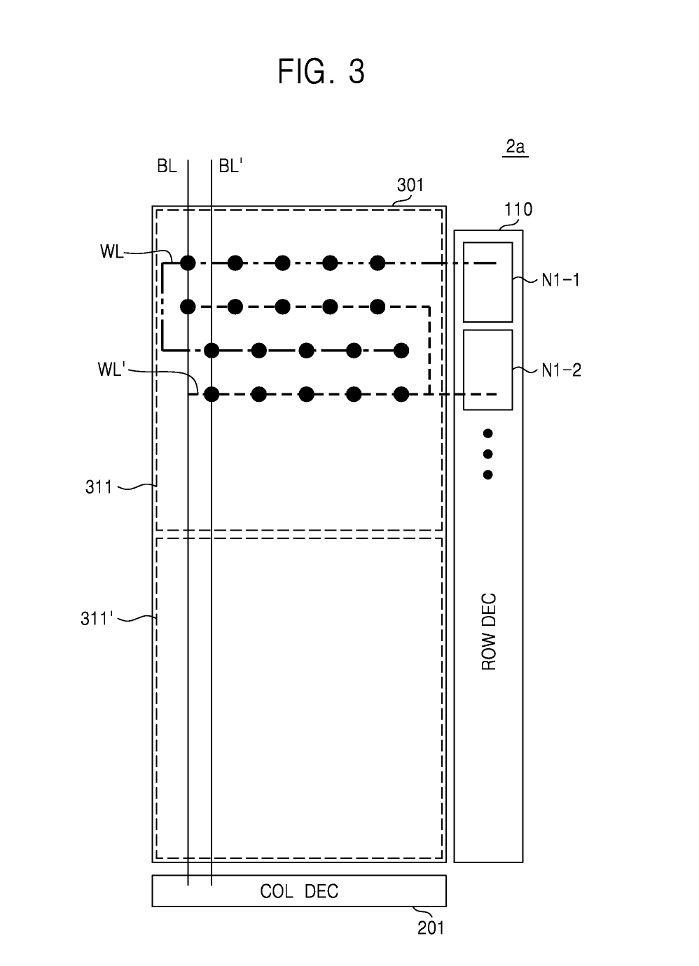

FIGS. 3 through 11 are block diagrams of examples of the antifuse device 1 illustrated in FIG. 1 according to some embodiments. It is assumed that a memory cell array includes 100 bit lines, 100 word lines, and antifuse memory cells connected between the bit lines and the word lines in the examples. It is also assumed that a column decoder has a length-to-width ratio of 1 and a row decoder has a length-to-width ratio of 1 with respect to the 100×100 memory cell array. These assumptions are just for convenience in the description and the disclosure is not restricted to these examples.

FIG. 3 is an exemplary block diagram of an example of the antifuse device 1 illustrated in FIG. 1 according to one embodiment. Referring to FIG. 3, an antifuse device 2a includes a memory cell array 301, a row decoder 110, and a column decoder 201. The memory cell array 301 includes a first sub array 311 and a second sub array 311′.

The sub arrays 311 and 311′ are arranged in line longitudinally (e.g., in a column direction). First ends of the respective word lines are connected to at least one row decoder 110 through the first side of the first and second sub arrays 311 and 311′. The word lines may extend in a row direction.

The memory cell array 301 may include 100 bit lines and 100 word lines. For example, in one embodiment, the length of the column decoder 201 is cut in half and the width doubles and the length of the row decoder 110 doubles and the width is cut in half.

For example, due to the greater length available in the row decoder 110, the drivers that comprise the row decoder can be arranged to have greater length and smaller width. However, the area of the column decoder 201 remains the same and the area of the row decoder 110 remains the same.

Each of the sub arrays 311 and 311′ may include 100 bit lines BL and 50 word lines WL. Each of bit lines BL is shared by the first and second sub arrays 311 and 311′ and connected to the column decoder 201 at the second side of the second sub array 311′, so that target memory cells are accessed. The word lines WL may be separated from one another in parallel or may be alternately separated from each other.

Referring to FIG. 3, a word line WL connected to a first word line driver N1-1 of the row decoder 110 and a word line WL′ connected to a second word line driver N1-2 of the row decoder 110 are folded alternating back and forth with space and they are arranged to face each other like clasped hands. For example, a first word line driver of the row decoder 110 generates a first word line selection signal and the first word line driver is electrically coupled to a first set of antifuse memory cells in response to the first word line selection signal. The first set of antifuse memory cells may be arranged in first and third rows. A second word line driver of the row decoder 110 generates a second word line selection signal and the second word line driver is electrically coupled to a second set of antifuse memory cells in response to the second word line selection signal. The second set of antifuse memory cells may be arranged in second and fourth rows. The third row is arranged between the second row and the fourth row. In one embodiment, a first bit line electrically coupled to the antifuse memory cell array may be connected to a third set of antifuse memory cells arranged in a first column. The third set of antifuse memory cells may include at least one antifuse memory cell of each of the first and second set of antifuse memory cells.

Antifuse memory cells in the word lines WL and WL′ alternating and facing each other are separately connected to a first bit line BL and a second bit line BL′ to be separately accessed.

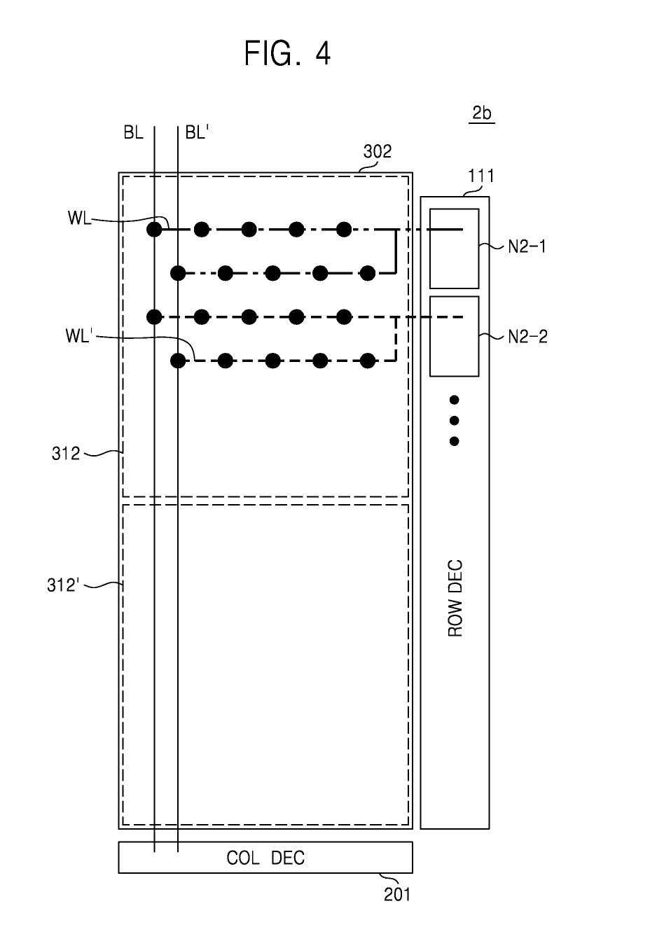

FIG. 4 is an exemplary block diagram of another example of the antifuse device 1 illustrated in FIG. 1 according to one embodiment. Differences between an antifuse device 2b illustrated in FIG. 4 and the antifuse device 2a illustrated in FIG. 3 will be mainly described.

Like the antifuse device 2a illustrated in FIG. 3, the antifuse device 2b also includes a first sub array 312 and a second sub array 312′ arranged in line longitudinally in a memory cell array 302. However, the arrangement of word lines is different from that illustrated in FIG. 3.

In the example illustrated in FIG. 4, folded word lines WL or WL′ are connected to a row decoder 111 through a first word line driver N2-1 or a second word line driver N2-2 of the row decoder 111. Unlike the word lines illustrated in FIG. 3, the word lines illustrated in FIG. 4 are not facing each other like clasped hands but are separated from each other in parallel. Antifuse memory cells positioned respectively in a first word line and a second word line, which are arranged to be separated from each other in parallel, are connected to a first bit line BL and a second bit line BL′, respectively, to be separately accessed.

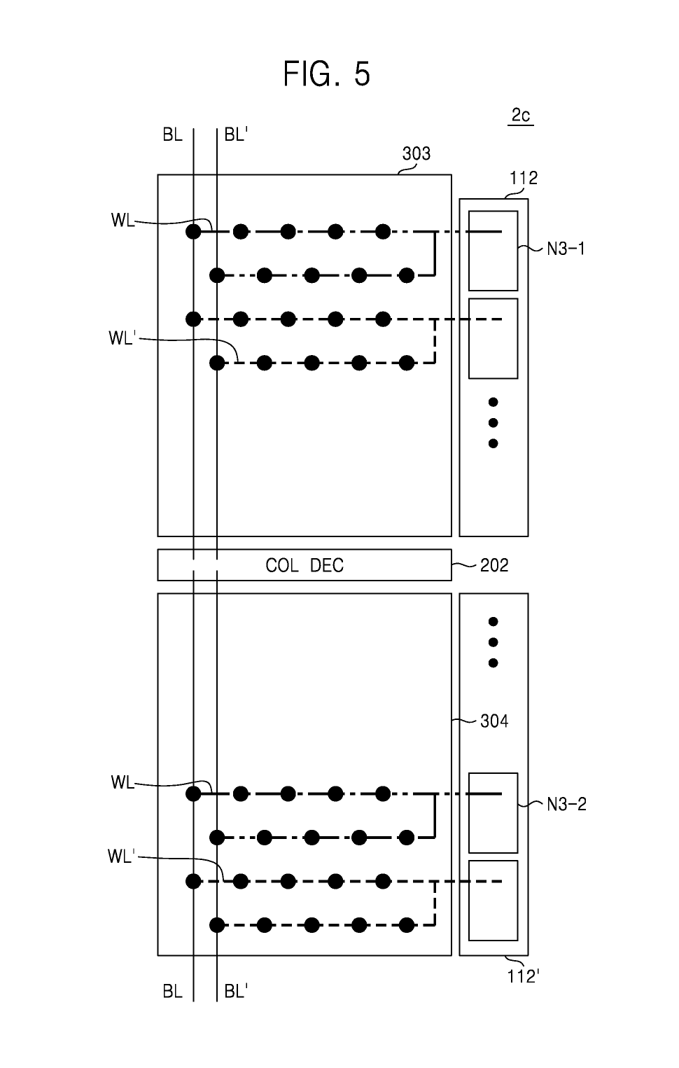

FIG. 5 is an exemplary block diagram of still another example of the antifuse device 1 illustrated in FIG. 1 according to one embodiment. Differences between an antifuse device 2c illustrated in FIG. 5 and the antifuse device 2a illustrated in FIG. 3 will be mainly described.

In the antifuse device 2c, a first sub array 303, a second sub array 304, and a column decoder 202 are arranged in line longitudinally. In other words, the first sub array 303 is positioned at one side of the column decoder 202 and the second sub array 304 is positioned at the other side of the column decoder 202. For example, the length of the column decoder 202 is cut in half, but the total area of the column decoder 202 is the same.

Accordingly, the column decoder 202 has the same area as the column decoder 201 shown in FIG. 3 or 4. However, unlike the antifuse device 2a shown in FIG. 3 or the antifuse device 2b shown in FIG. 4, each of the bit lines is not shared by the first and second sub arrays 303 and 304.

Moreover, the antifuse device 2c includes a first row decoder 112 and a second row decoder 112′ to respectively access the first and second sub arrays 303 and 304. In each of the first and second sub arrays 303 and 304, two word lines may be arranged in parallel with space as shown in FIG. 5 and may be connected to the row decoder 112 or 112′ through a first word line driver N3-1 or a second word line driver N3-2 of the row decoder 112. However, the disclosure is not restricted to the current example. As shown in FIG. 3, word lines may be folded alternating back and forth with space and arranged to alternate and face each other and may be connected to the row decoder 112 or 112′ through respective nodes.

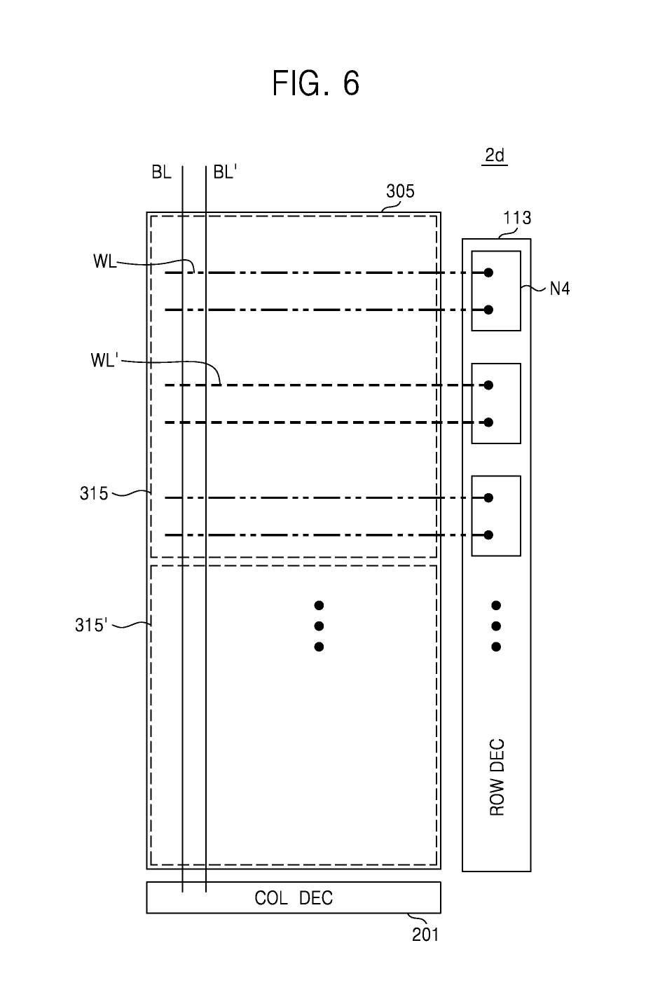

FIG. 6 is an exemplary block diagram of yet another example of the antifuse device 1 illustrated in FIG. 1 according to one embodiment. Differences between an antifuse device 2d illustrated in FIG. 6 and the antifuse device 2b illustrated in FIG. 4 will be mainly described.

As compared to the antifuse device 2b illustrated in FIG. 4, the antifuse device 2d illustrated in FIG. 6 has a different word lines arrangement in sub arrays 315 and 315′. In detail, while two word lines are connected to the row decoder 111 through the first or second word line drivers N2-1 or N2-2 of the row decoder 111 in the antifuse device 2b illustrated in FIG. 4, two word lines are connected through a first word line driver N4 of a row decoder 113.

For example, unlike the word lines shown in FIG. 3, the word lines shown in FIG. 6 do not have a folded structure. Antifuse memory cells positioned respectively in a first word line and a second word line, which are arranged to be separated from each other in parallel, are connected to a first bit line BL and a second bit line BL′, respectively, to be separately accessed.

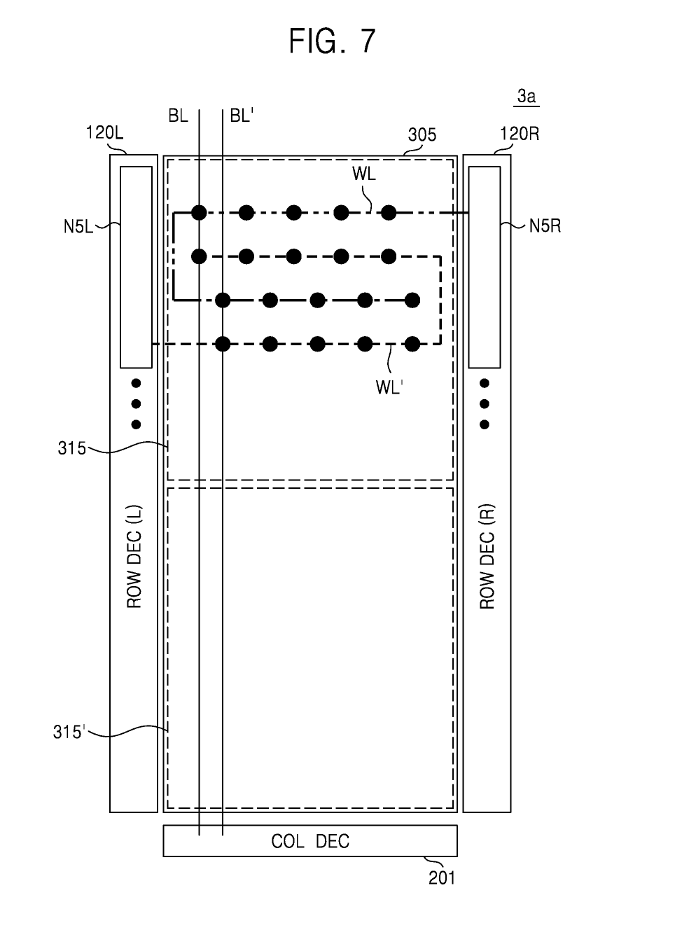

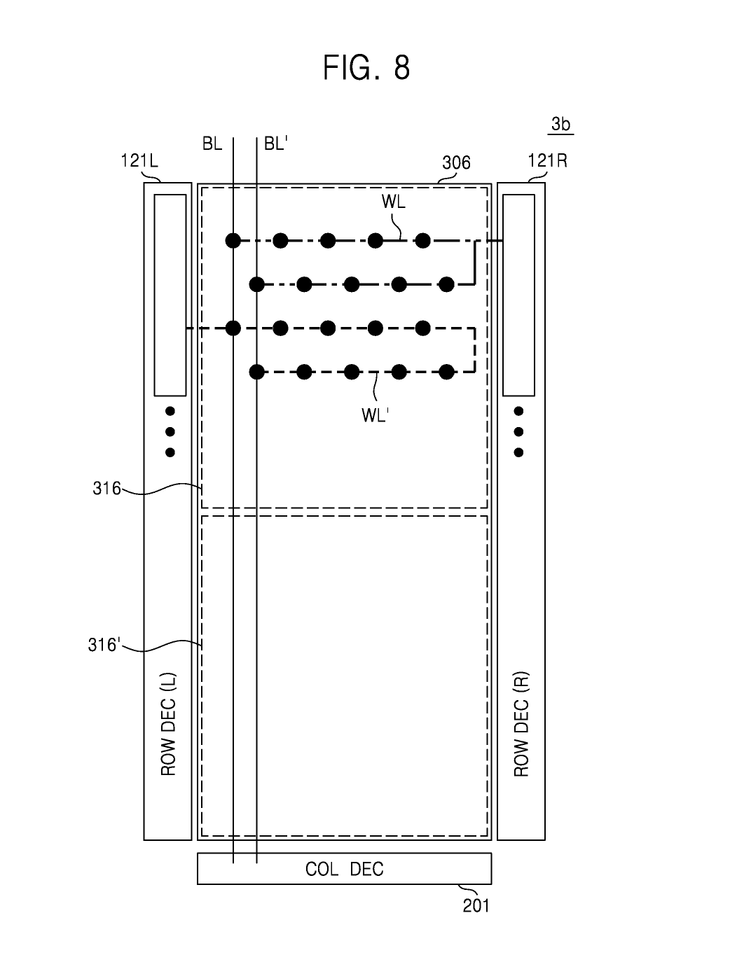

FIG. 7 is an exemplary block diagram of even another example of the antifuse device 1 illustrated in FIG. 1 according to one embodiment. FIG. 8 is an exemplary block diagram of further example of the antifuse device 1 illustrated in FIG. 1 according to one embodiment. Differences between the examples respectively illustrated in FIGS. 7 and 8 and the examples respectively illustrated in FIGS. 3 through 6 will be mainly described.

In an antifuse device 3a illustrated in FIG. 7, the first and second sub arrays 315 and 315′ are arranged in line longitudinally within the memory cell array 305. However, unlike the antifuse device 2a illustrated in FIG. 3, the antifuse device 3a includes row decoders 120L and 120R at both sides, respectively of the memory cell array 305. For example, the length of each of the row decoders 120L and 120R quadruples, but each of the row decoders 120L and 120R has a half area. Accordingly, a total area of the row decoders 120L and 120R is the same as the area of the row decoder 110.

Referring to FIG. 7, two word lines are connected to the row decoder 120L or 120R through a first word line driver N5L or a second word line driver N5R. Each of the 100 bit lines are shared by the first and second sub arrays 315 and 315′ and are connected to the column decoder 201 at the second side of the second sub array 315′ so that a target memory cell is accessed. The word lines may be arranged to be separated from each other in parallel or may be arranged to be separated alternating with each other.

For instance, as shown in FIG. 7, a word line WL connected to the first word line driver N5L and a word line WL′ connected to the second word line driver N5R are folded alternating back and forth with space and they are arranged to face each other like clasped hands. However, the row decoders 120L and 120R are respectively positioned at a third side of the memory cell array 305 and the first side opposite the third side unlike the row decoder 110 illustrated in FIG. 3, the word lines facing each other are respectively connected to the facing row decoders 120L and 120R to be accessed.

Antifuse memory cells in the word lines alternating and facing each other are separately connected to a first bit line BL and a second bit line BL′ to be separately accessed.

The arrangement of word lines in an antifuse device 3b illustrated in FIG. 8 may correspond to that in the antifuse device 2b illustrated in FIG. 4. However, differently from the antifuse device 2b illustrated in FIG. 4, the antifuse device 3b includes row decoders 121L and 121R respectively at the third side and the first side opposite the third side. Accordingly, word lines separated from each other in parallel are alternately connected to each of the row decoders 121L and 121R to be accessed.

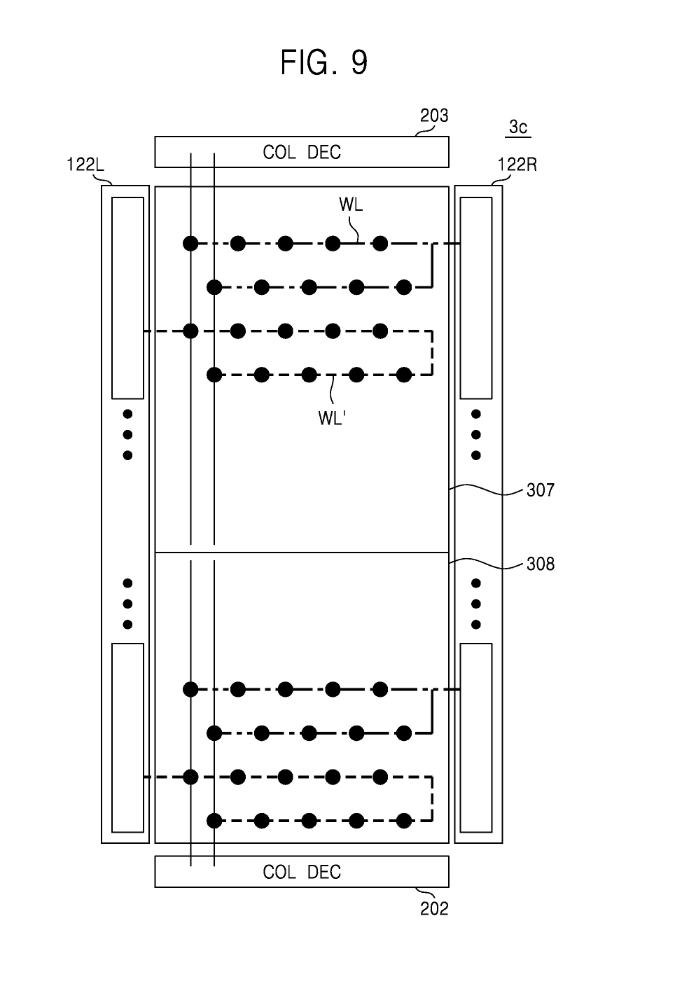

FIG. 9 is an exemplary block diagram of still further example of the antifuse device 1 illustrated in FIG. 1 according to one embodiment. Differences between an antifuse device 3c illustrated in FIG. 9 and the antifuse device 2c illustrated in FIG. 5 will be mainly described.

The antifuse device 3c illustrated in FIG. 9 includes a memory cell array including a first sub array 307 and a second sub array 308, a row decoder 122R at the first side, the column decoder 202 at the second side, a row decoder 122L at the third side, and a column decoder 203 at the fourth side. For example, the length of each of the row decoders 122L and 122R quadruples, but each of the row decoders 122L and 122R has a half area, so that a total area of the row decoders 122L and 122R is the same. The length of each of the column decoders 202 and 203 is cut in half, but each of the column decoders 202 and 203 has a half area, so that a total area of the column decoders 202 and 203 is the same.

Word lines are arranged to be separated from each other in parallel. However, the word lines are alternately connected to each of the row decoders 122L and 122R to be accessed. Although the arrangement of word lines illustrated in FIG. 9 is similar to that illustrated in FIG. 5, the disclosure is not restricted to the current example. Meanwhile, bit lines are not accessed by a single column decoder, but bit lines in the first sub array 307 are accessed by the first column decoder 203 and bit lines in the second sub array 308 are accessed by the second column decoder 202.

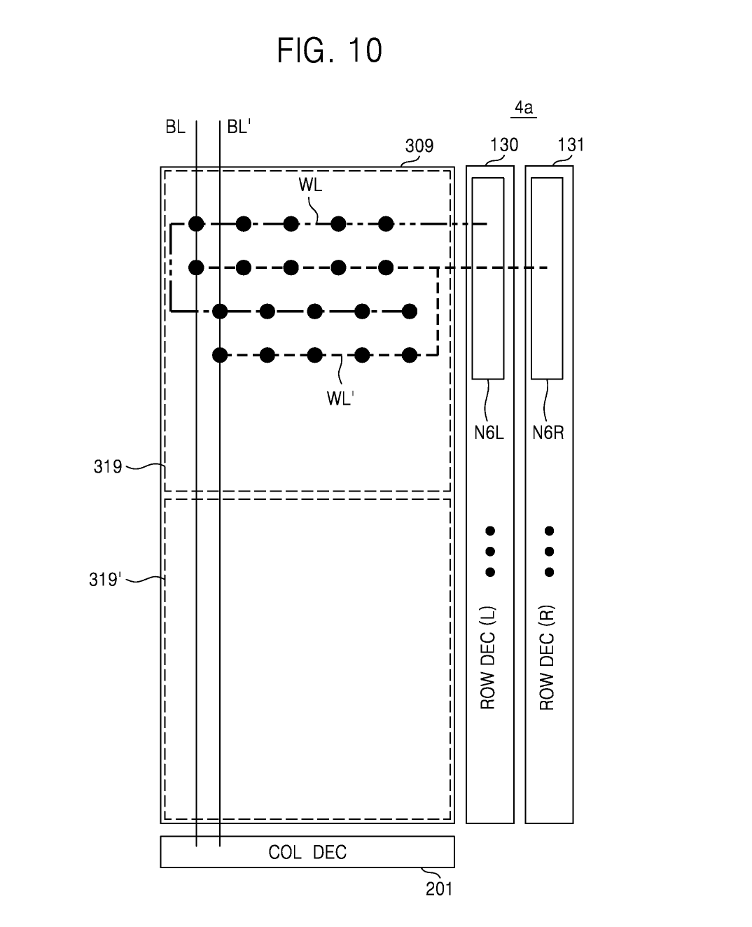

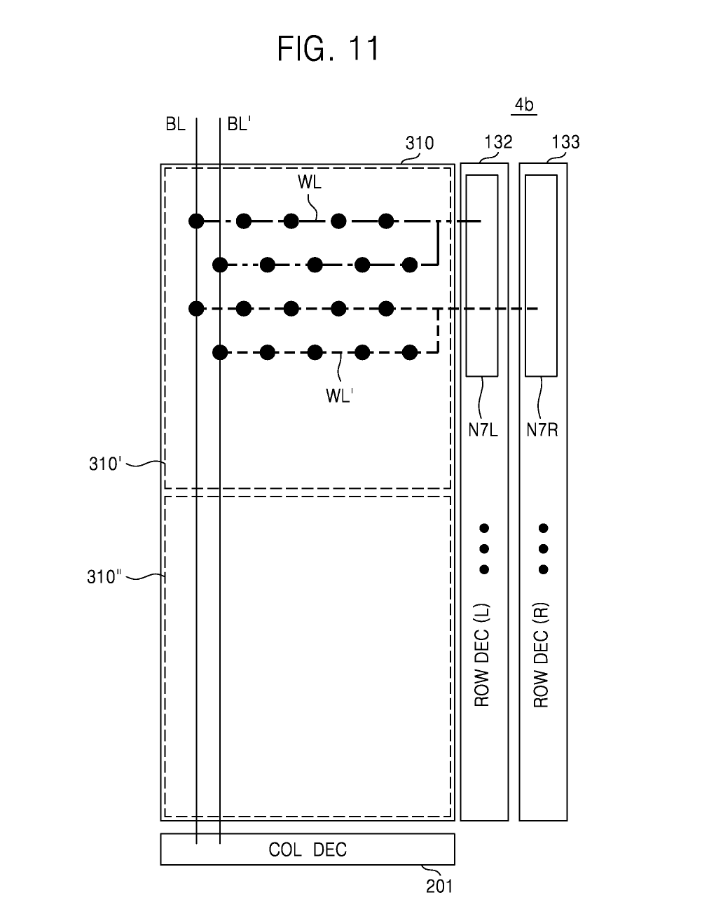

FIG. 10 is an exemplary block diagram of yet further example of the antifuse device 1 illustrated in FIG. 1 according to one embodiment. FIG. 11 is a block diagram of even further example of the antifuse device 1 illustrated in FIG. 1 according to one embodiment. Differences between the examples respectively illustrated in FIGS. 10 and 11 and the examples respectively illustrated in FIGS. 3 and 4 will be mainly described.

In each of antifuse devices 4a and 4b respectively illustrated in FIGS. 10 and 11, first and second word line drivers N6L and N6R or N7L and N7R respectively connected to word lines are not separated far away from each other but may be arranged side by side in two different row decoders 130 and 131 or 132 and 133, respectively. For example, the length of each of the row decoders 130 and 131 or 132 and 133 quadruples, but each of the row decoders 130 and 131 or 132 and 133 has a half area. Accordingly, a total area of the row decoders 130 and 131 or 132 and 133 is the same.

The arrangement of word lines within memory cell arrays 309 and 310 may be implemented as shown in FIGS. 10 and 11, but the disclosure is not restricted to those examples.

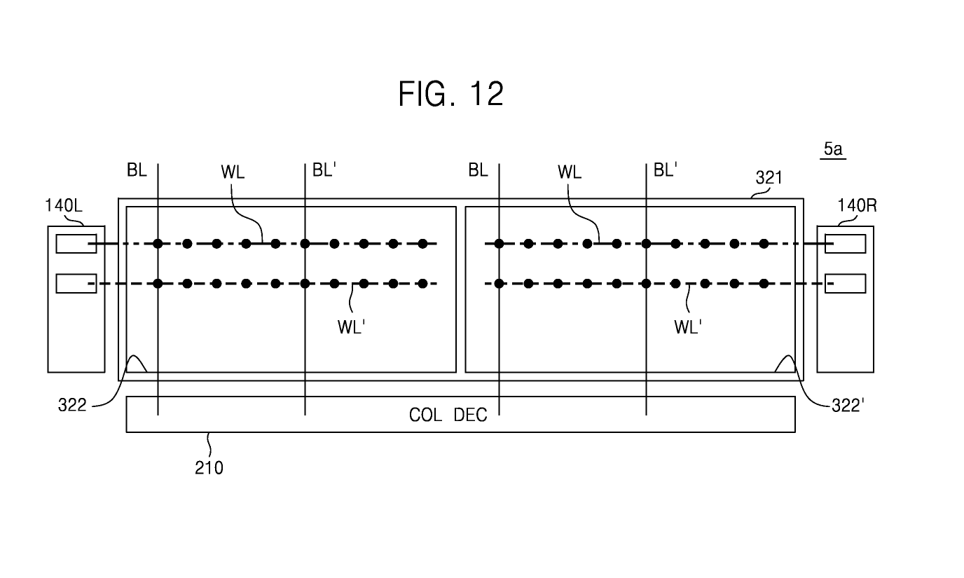

FIGS. 12 through 15 are block diagrams of other examples of the antifuse device 1 illustrated in FIG. 1 according to some embodiments. It is assumed that a memory cell array includes 100 bit lines, 100 word lines, and antifuse memory cells connected between the bit lines and the word lines in the examples. It is also assumed that a column decoder has a length-to-width ratio of 1 and a row decoder has a length-to-width ratio of 1 with respect to the 100×100 memory cell array. It is also assumed that the memory cell array divides 100 bit lines into one group and 100 word lines into two groups, thereby including a total of two (i.e., 2×1=2) sub arrays. These assumptions are just for convenience in the description and the disclosure is not restricted to these examples.

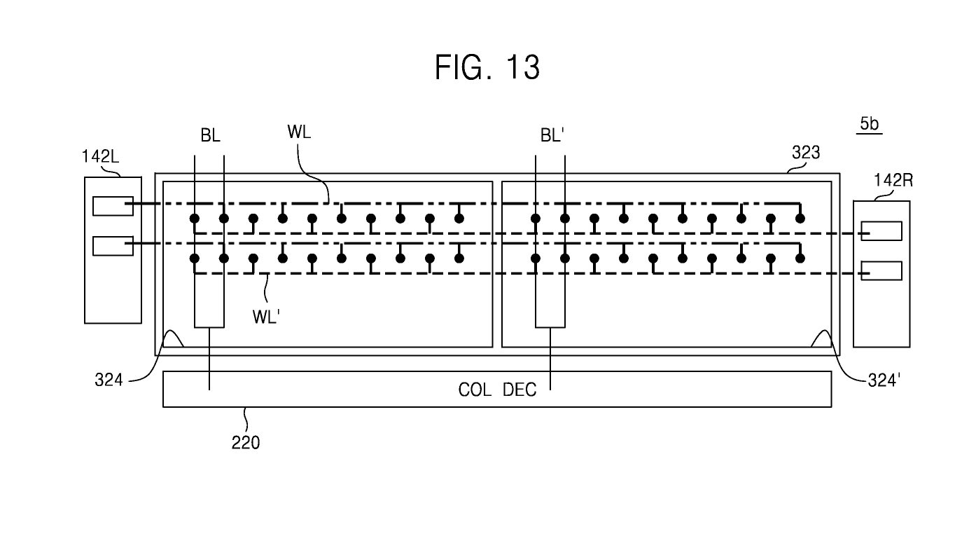

FIG. 12 is an exemplary block diagram of yet further example of the antifuse device 1 illustrated in FIG. 1 according to one embodiment. FIG. 13 is an exemplary block diagram of yet further example of the antifuse device 1 illustrated in FIG. 1 according to one embodiment.

Referring to FIG. 12, an antifuse device 5a includes a memory cell array 321, a first row decoder 140R, a second row decoder 140L, and a column decoder 210. The memory cell array 321 includes a first sub array 322 and a second sub array 322′. The first row decoder 140R at a first side of the memory cell array 321 and a second row decoder 140L at a third side opposite to the first side of the memory cell array 321. The column decoder 210 is positioned at a second side of the memory cell array 321 perpendicular to the first and third sides and accesses bit lines in the first and second sub arrays 322 and 322′.

The sub arrays 322 and 322′ are arranged in line laterally. First ends of the respective word lines are connected to at least one row decoder 140L or 140R through the first or third side of the first and second sub arrays 322 and 322′.

The memory cell array 321 is comprised of 200 bit lines and 50 word lines. For example, the length of the column decoder 201 doubles and the length of each of the row decoders 140L and 140R is cut in half. However, the area of the column decoder 210 remains the same. The area of each of the row decoders 140L and 140R is half, and therefore, the total area of the first and second row decoders 140R and 140L remains the same.

Each of the sub arrays 322 and 322′ includes 100 bit lines BL and 50 word lines WL. The sub arrays 322 and 322′ are accessed by the first and second row decoders 140R and 140L, respectively, and by the column decoder 210 in common. As shown in FIG. 12, each antifuse memory cell may be positioned at the intersection between a word line WL and a bit line BL and antifuse memory cells in the word line WL may be arranged to be parallel to another word line.

An antifuse device 5b illustrated in FIG. 13 is almost the same as the antifuse device 5a illustrated in FIG. 12 except for the arrangement of antifuse memory cells. In detail, antifuse memory cells may be positioned between two parallel word lines and alternately connected to the two word lines. Bit lines separated from each other in parallel are respectively connected to antifuse memory cells alternately and respectively connected to the word lines and are connected to the column decoder 210 through a single node.

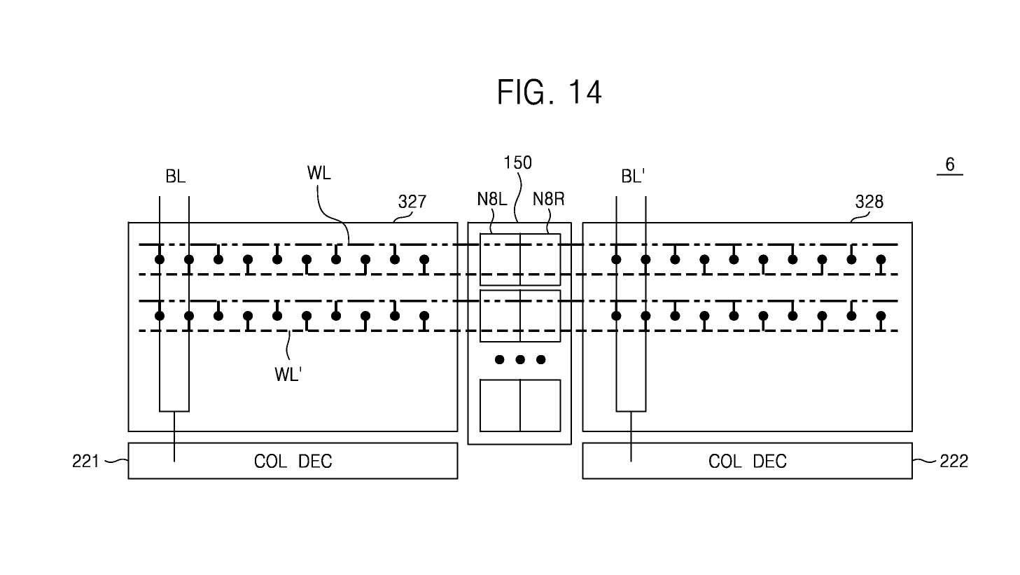

FIG. 14 is an exemplary block diagram of yet further example of the antifuse device 1 illustrated in FIG. 1 according to one embodiment. Differences between the example illustrated in FIG. 14 and the examples respectively illustrated in FIGS. 12 and 13 will be mainly described.

Unlike the antifuse devices 5a and 5b illustrated in FIGS. 12 and 13, an antifuse device 6 illustrated in FIG. 14 includes a row decoder 150 between a first sub array 327 and a second sub array 328. The row decoder 150 includes a first word line driver N8L and a second word line driver N8R side by side and accesses the first and second sub arrays 327 and 328 through the first and second drivers N8L and N8R, respectively. In other words, each of the word lines shares the first and second word line drivers N8L and N8R of the row decoder 150.

A column decoder 221 is positioned at the second side of the sub array 327 and a column decoder 222 is positioned at the second side of the sub array 328. For example, bit lines crossing the word lines may be arranged to be separated from each other in parallel, as shown in FIG. 12. Alternatively, bit lines separated from each other in parallel are respectively connected to antifuse memory cells alternately and respectively connected to the word lines and are connected to the column decoder 221 or 222 through a single node of the column decoders 221 and 222.

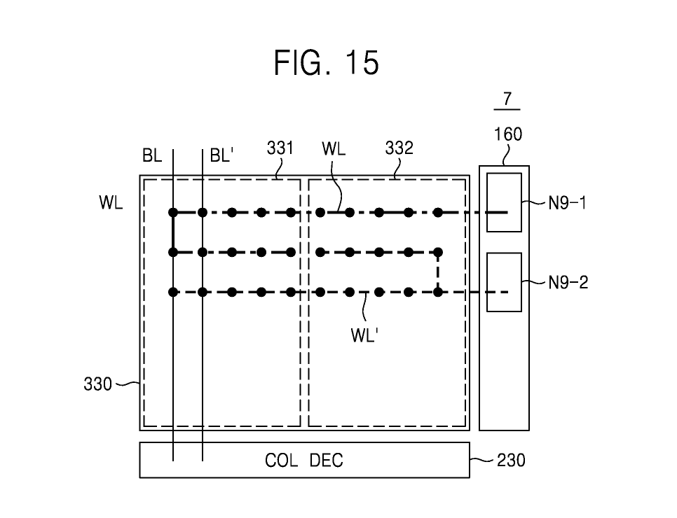

FIG. 15 is an exemplary block diagram of yet further example of the antifuse device 1 illustrated in FIG. 1 according to one embodiment. Differences between the example illustrated in FIG. 15 and the examples respectively illustrated in FIGS. 12 through 14 will be mainly described.

Unlike the antifuse devices 5a, 5b, and 6 illustrated in FIGS. 12 through 14, an antifuse device 7 illustrated in FIG. 15 includes a row decoder 160 at the first side of a memory cell array 330. A first sub array 331 and a second sub array 332 may share the row decoder 160 positioned at the first side of the second sub array 332. For example, folded word lines extending over both of the first and second sub arrays 331 and 332 may be alternately arranged to face each other.

As described with reference to FIGS. 3 through 15, an antifuse device is flexibly designed in light of division of a memory cell array into sub arrays, word line arrangement, bit line arrangement, row/column decoder arrangement and so on according to a chip shape and layout design. As a result, the layout of a chip can be variously modified in the same area, thereby enabling chip space to be efficiently used.

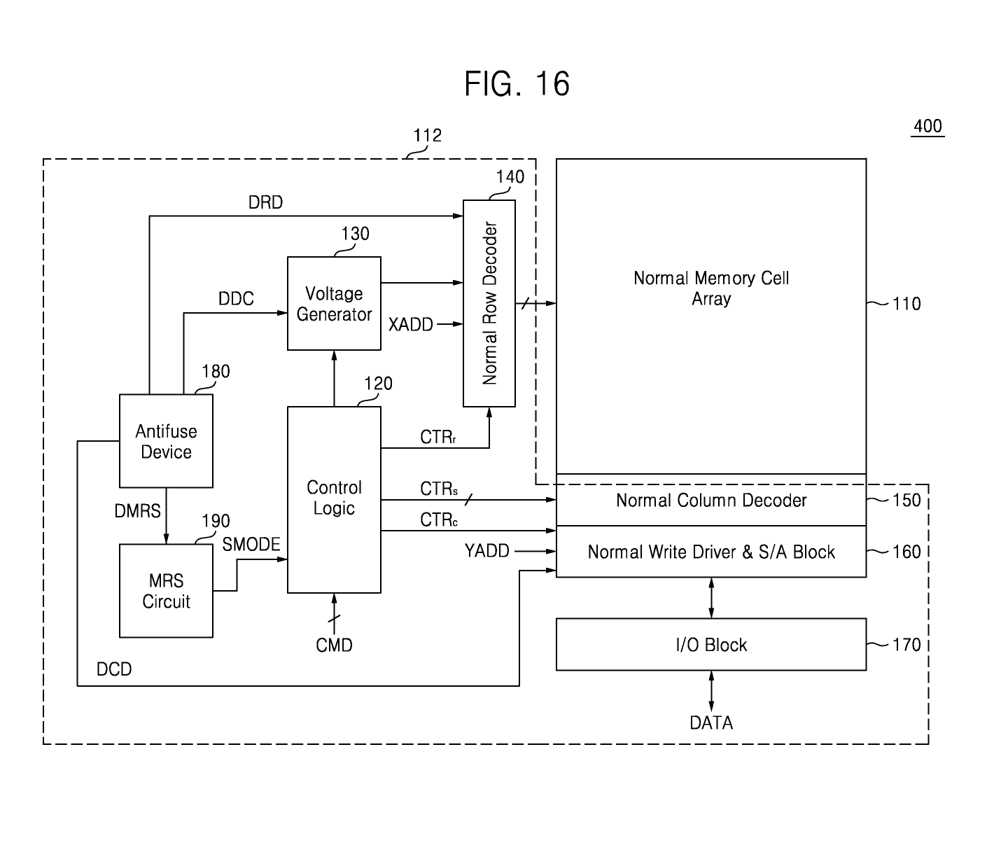

FIG. 16 is an exemplary block diagram of a memory device 400 according to some embodiments. Referring to FIG. 16, the memory device 400 may include a normal memory cell array 110 and a control circuit 112. The normal memory cell array 110 includes a plurality of normal memory cells and is electrically connected to a plurality of normal bit lines and a plurality of normal word lines. The control circuit 112 may include an antifuse device according to certain embodiments disclosed herein.

The memory device 400 may be implemented by a volatile or non-volatile memory device. The volatile memory device may include, for example, dynamic random access memory (DRAM), static RAM (SRAM), thyristor RAM (T-RAM), zero capacitor RAM (Z-RAM), or twin transistor RAM (TTRAM).

The non-volatile memory device may include, for example, electrically erasable programmable read-only memory (EEPROM), flash memory, magnetic random access memory (MRAM), spin-transfer torque MRAM, conductive bridging RAM (CBRAM), ferroelectric RAM (FeRAM), phase-change RAM (PRAM), resistive RAM (RRAM), nanotube RRAM, polymer RAM (PoRAM), nano floating gate memory (NFGM), holographic memory, molecular electronic memory device, or insulator resistance change memory.

The normal memory cell array 110 may include a plurality of normal memory cells storing data. The normal cell array 110 may be implemented in a two- or three-dimensional structure.

The control circuit 112 may access the normal memory cell array 110 to perform a data access operation, e.g., a read operation, according to a set of commands CMD, XADD, and YADD received from an external device, e.g., a memory controller (not shown). In one embodiment, the control circuit 112 controls the normal memory cell array 110 to perform a program operation (or a write operation), a read operation, or an erase operation.

The control circuit 112 includes a control logic 120, a voltage generator 130, a normal row decoder 140, a normal column decoder 150, a normal write driver and sense amplifier (S/A) block 160, an input/output (I/O) block 170, an antifuse device 180, and a mode register set (MRS) circuit 190.

The control logic 120 may control the overall operation of the control circuit 112 in response to a command (e.g., CMD) included in a command set. The voltage generator 130 may generate a voltage used for the data access operation according to a control code generated by the control logic 120. Although the voltage generated by the voltage generator 130 is applied to the normal row decoder 140 in FIG. 16 for convenience' sake in the description, the disclosure is not restricted thereto.

The normal row decoder 140 may decode the normal row address XADD according to a control signal CTR received from the control logic 120. The normal column decoder 150 may decode the normal column address YADD under the control of the control logic 120.

The normal write driver and S/A block 160 may function as a sense amplifier that can sense and amplify a voltage level of each of a plurality of normal bit lines included in the normal memory cell array 110 according to the control of the control logic 120 when the memory device 400 performs the read operation. The normal write driver and S/A block 160 may function as a write driver that can drive each of the normal bit lines included in the normal memory cell array 110 according to the control of the control logic 120 when the memory device 400 performs the write operation.

The I/O block 170 may transmit data received from an external device to the normal column decoder 150 through the normal write driver and S/A block 160 and transmit data output from the normal column decoder 150 to a device outside the memory device 400, e.g., the memory controller (not shown). The antifuse device 180 according to certain embodiments may store trimming data DDC related to the trimming a level of voltage or a level of current used for the operation of the memory device 400.

The trimming data DDC may include information about the level of voltage or current used when the voltage generator 130 trims a voltage or a current.

The antifuse device 180 may store defective cell address data related to defective cells in the memory device 400. For instance, the antifuse device 180 may store row data DRD including a normal row address of the defective cells or column data DCD including a normal column address of the defective cells.

The antifuse device 180 may store MRS data DMRS related to the setting of the MRS circuit 190. The MRS data DMRS may include information, e.g., an operating frequency and/or a direct current (DC) voltage level, used for the operation of the memory device 400 according to the operation mode of the memory device 400.

The trimming data DDC read from the antifuse device 180 may be transmitted to the voltage generator 130. The voltage generator 130 may generate a voltage based on the trimming data DDC. The row data DRD read from the antifuse device 180 may be transmitted to the normal row decoder 140. The normal row decoder 140 may decode the normal row address XADD based on the row data DRD.

When the normal row address XADD is the same as the normal row address of a defective normal cell, the normal row decoder 140 may remap the normal row address XADD to a normal row address of a redundancy cell corresponding to the defective normal cell.

The column data DCD read from the antifuse device 180 may be transmitted to the normal column decoder 150. The normal column decoder 150 may decode the normal column address YADD based on the column data DCD.

When the normal column address YADD is the same as the normal column address of a defective normal cell, the normal column decoder 150 may remap the normal column address YADD to a normal column address of a redundancy cell corresponding to the defective normal cell.

The MRS data DMRS read from the antifuse device 180 may be transmitted to the MRS circuit 190.

The MRS circuit 190 may include a mode register (not shown). The MRS unit 190 may set a mode register (not shown) included in the MRS circuit 190 based on the MRS data DMRS read from the antifuse device 180. The MRS circuit 190 may send a mode signal SMODE to the control logic 120. The control logic 120 may control the overall operation of the memory device 400 based on the mode signal SMODE.

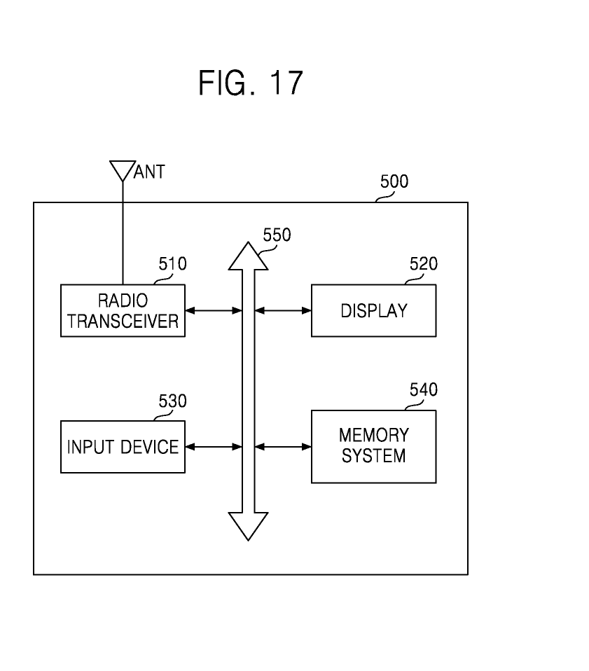

FIG. 17 is an exemplary block diagram of a data processing system 500 including a memory according to some embodiments. Referring to FIG. 17, the data processing system 500 may be implemented as a cellular phone, a smart phone, a tablet personal computer (PC), a personal digital assistant (PDA) or a radio communication system.

The data processing system 500 may include a memory system 540. The memory system 540 may include a memory device and a memory controller controlling the operations of the memory device. The memory device may include the antifuse device as disclosed herein. The memory controller may control the data access operations, e.g., a program operation, an erase operation, and a read operation, of the memory device according to the control of a processor.

The page data programmed in the memory device may be displayed through a display 520 according to the control of the processor and/or the memory controller.

A radio transceiver 510 transmits or receives radio signals through an antenna ANT. The radio transceiver 510 may convert radio signals received through the antenna ANT into signals that can be processed by the processor. Accordingly, the processor (not shown) may process the signals output from the radio transceiver 510 and transmit the processed signals to the memory system 540 or the display 520. The radio transceiver 510 may also convert signals output from the processor into radio signals and outputs the radio signals to an external device through the antenna ANT.

An input device 530 enables control signals for controlling the operation of the processor or data to be processed by the processor to be input to the data processing system 500. The input device 530 may be implemented by a pointing device such as a touch pad or a computer mouse, a keypad, or a keyboard.

The processor may control the operation of the display 520 to display data output from the memory system 540, data output from the radio transceiver 510, or data output from the input device 530. The memory controller, which controls the operations of the memory device, and the memory device may be implemented as a stacked structure.

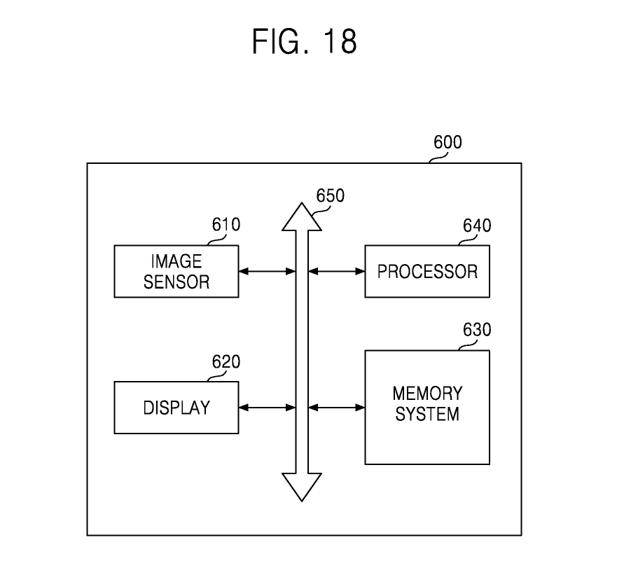

FIG. 18 is an exemplary block diagram of a data processing system 600 including the memory system according to some embodiments. Referring to FIG. 18, the data processing system 600 may be implemented as an image processor like a digital camera, a cellular phone equipped with a digital camera, a smart phone equipped with a digital camera, or a tablet PC equipped with a digital camera.

The data processing system 600 may include an image sensor 620, a display 620, a memory system 630, a processor 640, and a bus 650.

The memory system 630 may include a memory device and a memory controller controlling the data processing operations of the memory device. The memory device may include the antifuse device as disclosed herein.

The image sensor 610 included in the data processing system 600 converts optical images into digital signals and outputs the digital signals to the memory system 630. The digital signals may be displayed through a display 620 or stored in the memory device through the memory controller.

Data stored in the memory device may be displayed through the display 620. The memory controller (not shown), which may control the operations of the memory device, may be implemented as a part of the processor 640 or as a separate chip.

Each of elements is connected via the bus 650.

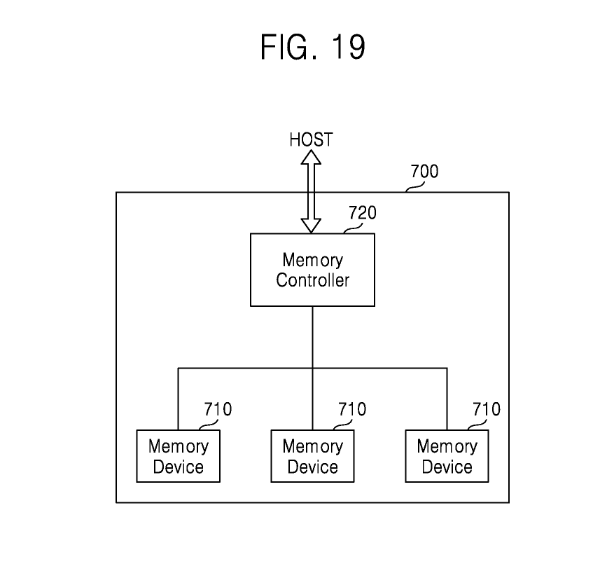

FIG. 19 is an exemplary block diagram of a data processing system 700 including a plurality of memory devices according to some embodiments. Referring to FIG. 19, the data processing system 700 may be implemented as a data storage system like a solid state drive (SSD).

The data processing system 700 includes a plurality of memory devices 710, and a memory controller 720 controlling the data processing operations of the memory devices 710. Each of the memory devices 710 may include the antifuse device disclosed herein.

The data processing system 700 may be implemented as a memory module.

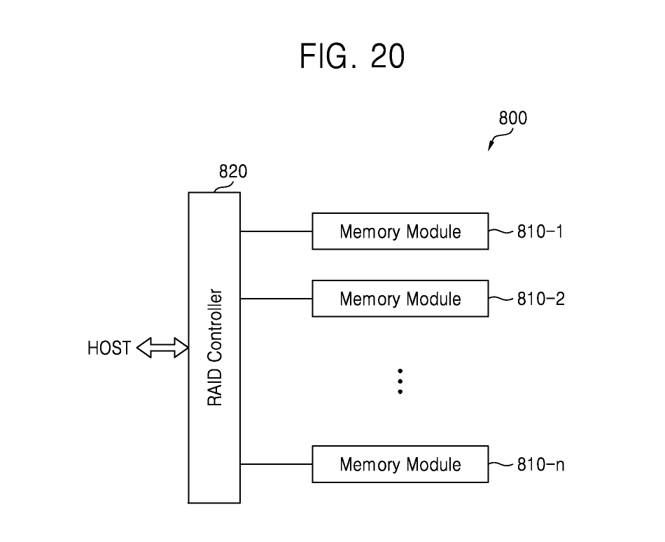

FIG. 20 is an exemplary block diagram of a data storage system 800 including a plurality of memory modules according to some embodiments. Referring to FIG. 20, the data storage system 800 may be implemented as a redundant array of independent disks (RAID) system. The data storage system 800 may include a RAID controller 820 and a plurality of memory modules 810-1 through 810-n where “n” is a natural number.

Each of the memory modules 810-1 through 810-n may be the data processing system 700 illustrated in FIG. 19. The memory modules 810-1 through 810-n may form a RAID array. The data storage system 800 may be a PC or an SSD.

During a program operation, the RAID controller 820 may transmit program data output from a host to at least one of the memory modules 810-1 through 810-n according to a RAID level in response to a program command received from the host. During a read operation, the RAID controller 820 may transmit to the host data read from at least one of the memory modules 810-1 through 810-n in response to a read command received from the host.

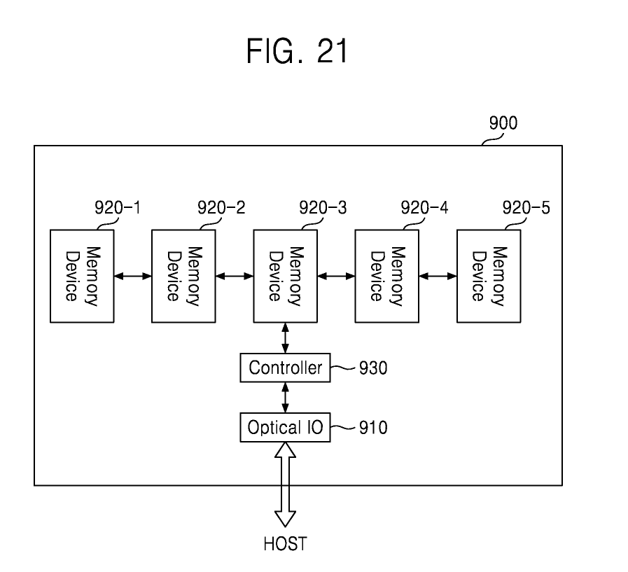

FIG. 21 is an exemplary block diagram of a memory module 900 including a plurality of memory devices according to some embodiments. Referring FIG. 21, the memory module 900 may include a plurality of memory devices 920-1 through 920-5, a memory controller 930, and an optical interface 910 for interfacing data input/output of each of the plurality of memory devices 920-1 through 920-5.

The optical interface 910 may include an input/output control device for controlling data input/output of each of the plurality of memory devices 920-1 through 920-5, and a signal converting device for converting data input or output from the memory device to optical signal.

The optical interface 910 provides data exchange between each of the plurality of memory devices 920-1 through 920-5 and a host using optical communication. The optical interface 910 may transmit or receive data using an optical fiber or a waveguide.

The exchanged data may be suitable for transceiving high speed signal like serial ATA (SATA) standard signal.

The memory controller 930, which may control the operations of the memory devices 920-1 through 920-5, may be implemented as a part of the memory devices 920-1 through 920-5 or as a stacked structure with the memory devices 920-1 through 920-5.

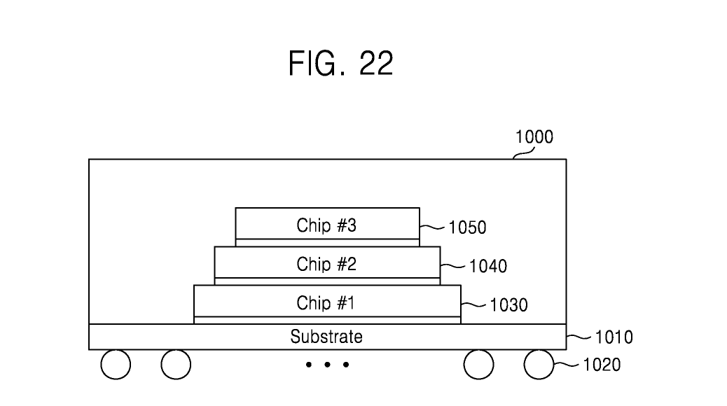

FIG. 22 is an exemplary schematic conceptual diagram of a multi-chip package 1000 including a plurality of semiconductor devices according to some embodiments. Referring to FIG. 22, the multi-chip package 1000 may include a plurality of semiconductor devices, i.e., first through third chips 1030, 1040, and 1050 which are sequentially stacked on a package substrate 1010. Each of the semiconductor devices 1030 through 1050 may be the memory controller or the memory device. The memory device may include the antifuse device disclosed herein. A through-substrate via (TSV, e.g., through-silicon via) (not shown), a bonding wire (not shown), a bump (not shown), or a solder ball 1020 may be used to electrically connect the semiconductor devices 1030 through 1050 with one other.

As described above, according to some embodiments, a memory device and a memory system including the same allow memory cell array design and row/column decoder layout to be modified in various ways, thereby enabling a chip space area to be efficiently used.

While the disclosure has been particularly shown and described with reference to exemplary embodiments thereof, it will be understood by those of ordinary skill in the art that various changes in forms and details may be made therein without departing from the spirit and scope of the present disclosure as defined by the following claims.

What is claimed is:

1. A memory device including a memory cell array including a plurality of antifuse memory cells electrically coupled to a plurality of bit lines and a plurality of word lines, the memory device comprising:
a column decoder configured to select one bit line among the plurality of bit lines; and
a row decoder configured to select one word line among the plurality of word lines,
wherein the row decoder comprises:
a first word line driver configured to output a first word line selection signal to a first word line, the first word line driver electrically coupled to a first set of antifuse memory cells coupled to the first word line; and
a second word line driver configured to output a second word line selection signal to a second word line, the second word line driver electrically coupled to a second set of antifuse memory cells coupled to the second word line,
wherein the first set of antifuse memory cells are arranged in first and third rows of the memory cell array, and the second set of antifuse memory cells are arranged in second and fourth rows of the memory cell array, the second row being arranged between the first and third rows.

2. The memory device of claim 1, wherein the column decoder is arranged at a first side of the memory cell array, and
wherein the row decoder is arranged at a second side of the memory cell array perpendicular to the first side.

3. The memory device of claim 1, wherein the column decoder comprises:
a first column decoder arranged at a first side of the memory cell array; and
a second column decoder arranged at a second side of the memory cell array opposite to the first side,
wherein the row decoder is arranged at a third side of the memory cell array perpendicular to the first and second sides.

4. The memory device of claim 1, wherein the first word line driver is arranged at a first side of the memory cell array and the second word line driver is arranged at a second side of the memory cell array opposite to the first side, and
wherein the column decoder is arranged at a third side of the memory cell array perpendicular to the first and second sides.

5. The memory device of claim 1, wherein the column decoder comprising:
a first column decoder arranged at a first side of the memory cell array; and
a second column decoder arranged at a second side of the memory cell array opposite to the first side,
wherein the first word line driver is arranged at a third side of the memory cell array perpendicular to the first and second sides and the second word line driver is arranged at a fourth side of the memory cell array opposite to the third side.

6. The memory device of claim 1, wherein first word line driver is arranged at a first side of the memory cell array and a second word line driver is arranged at the first side, and is located between the memory cell array and the first word line driver.

7. A memory device comprising:
a memory cell array comprising a plurality of sub arrays, each of the sub arrays comprising a plurality of antifuse memory cells arranged in rows and columns and electrically coupled to a plurality of bit lines and a plurality of word lines;
a column decoder configured to output a plurality of bit line selection signals, and to select one bit line among the bit lines in response to one of the bit line selection signals;
a first row decoder configured to output a first word line selection signal and to select a first word line in response to the first word line selection signal, the first row decoder electrically coupled to a first set of antifuse memory cells arranged in a first row and a third row;
a second row decoder configured to output a second word line selection signal and to select a second word line in response to the second word line selection signal, the second row decoder electrically coupled to a second set of antifuse memory cells arranged in a second row and a fourth row; and
a sense amplifier configured to sense and amplify data of a selected antifuse memory cell,
wherein the second row is arranged between the first and third rows.

8. The memory device of claim 7, wherein the plurality of sub arrays are arranged in a column direction and each of the sub arrays shares a first bit line extending across the sub arrays in the column direction,
wherein the column decoder is arranged at a first side of the memory cell array, and
wherein the first and second row decoders are arranged at a second side of the memory cell array perpendicular to the first side.

9. The memory device of claim 7, wherein the column decoder comprises:
a first column decoder arranged at a first side of the memory cell array; and
a second column decoder arranged at a second side of the memory cell array opposite to the first side.

10. The memory device of claim 7, wherein the first row decoder is arranged at a first side of the memory cell array and the second row decoder is arranged at a second side of the memory cell array opposite to the first side.

11. The memory device of claim 10, wherein the column decoder comprises:
a first column decoder arranged at a third side of the memory cell array perpendicular the first and second sides; and
a second column decoder arranged at a fourth side of the memory cell array opposite to the third side.

12. The memory device of claim 7, wherein the plurality of sub arrays are arranged in a row direction and each of the sub arrays shares at least one word line extending across the sub arrays in the row direction,
wherein the column decoder is arranged at a first side of the memory cell array, and
wherein the first and second row decoders are arranged at a second side of the memory cell array perpendicular to the first side.

13. The memory device of claim 12, wherein the first and second row decoders are located parallel to each other between a first sub array of the plurality of sub arrays and a second sub array of the plurality of sub arrays,
wherein a first column decoder of the column decoder is arranged at a first side of the first sub array, and a second column decoder of the column decoder is arranged at a first side of the second sub array.

14. The memory device of claim 7, wherein the first row decoder is arranged at a first side of the memory cell array and the second row decoder is arranged at the first side, and is located between the memory cell array and the first row decoder.

15. An antifuse device comprising:
an antifuse memory cell array comprising a plurality of antifuse memory cells arranged in rows and columns and electrically coupled to a plurality of bit lines and a plurality of word lines;
a column decoder configured to be electrically coupled to the bit lines, to output a plurality of bit line selection signals, and to select one bit line among the bit lines in response to one of the bit line selection signals; and
a row decoder comprising:
a first word line driver configured to output a first word line selection signal, the first word line driver electrically coupled to a first set of antifuse memory cells arranged in first and third rows; and
a second word line driver configured to output a second word line selection signal, the second word line driver electrically coupled to a second set of antifuse memory cells arranged in second and fourth rows,
wherein the third row is arranged between the second row and the fourth row,
wherein a first bit line electrically coupled to the antifuse memory cell array is connected to a third set of antifuse memory cells arranged in a first column, and
wherein the third set of antifuse memory cells includes at least one antifuse memory cell of each of the first and second set of antifuse memory cells.

16. The antifuse device of claim 15, wherein the column decoder is arranged at a first side of the memory cell array, and
wherein the row decoder is arranged at a second side of the memory cell array perpendicular to the first side.

17. The antifuse device of claim 15, wherein the first word line driver is arranged at a first side of the memory cell array and the second word line driver is arranged at a second side of the memory cell array opposite to the first side, and
wherein the column decoder is arranged at a third side of the memory cell array perpendicular to the first and second sides.

18. The antifuse device of claim 17, wherein the column decoder comprises:
a first column decoder arranged at a third side of the memory cell array perpendicular the first and second sides; and
a second column decoder arranged at a fourth side of the memory cell array opposite to the third side.

19. The antifuse device of claim 15, wherein the first word line driver is arranged at a first side of the memory cell array and the second word line driver is arranged at the first side, and is located between the memory cell array and the first word line driver.

20. A memory device comprising:
the antifuse device of claim 15, the antifuse device configured to generate a first signal and a second signal;
a normal memory cell array including a plurality of normal memory cells each connected to a normal word line and a normal bit line;
a normal row decoder electrically coupled to the normal word line and configured to be controlled in response to the first signal; and
a normal column decoder electrically coupled to the normal bit line and configured to be controlled in response to the second signal.
